(19) United States
(12) Patent Application Publication
(10) Pub. No.: US 2012/0168795 A1
(43) Pub. Date: Jul. 5, 2012

(54) LIGHT EMITTING DIODE PACKAGE AND METHOD FOR MANUFACTURING SAME

(75) Inventor: Hong-Zhi LIU, Taoyuang (TW)

(73) Assignee: Intematix Technology Center Corporation, Taoyuang (TW)

(21) Appl. No.: 13/088,513

(22) Filed: Apr. 18, 2011

(30) Foreign Application Priority Data
Dec. 31, 2010 (TW) 099147331

(51) Int. Cl. H01L 33/58; H01L 33/52

(52) U.S. Cl. 257/98; 438/27; 257/E33.073; 257/E33.059

(57) ABSTRACT

A light emitting diode (LED) package and the manufacturing method thereof are provided. The LED package comprises a substrate, at least one LED die, a lens and an in-mold decoration film, wherein the LED die is fixed on the substrate; the lens is convexly molded on the substrate to encapsulate the LED die; and the in-mold decoration film has at least one phosphor layer disposed on the lens and a surface treatment layer disposed on the phosphor layer.

### FIELD OF THE INVENTION

The invention relates generally to a light emitting diode (LED) device and a method for manufacturing the same, and more particularly, relates to a LED package utilizing an in-mold decoration film and a method for manufacturing the same.

### BACKGROUND OF THE INVENTION

As energy-saving issue has been getting more and more attentions, LED illumination has become one of the popular lighting applications now. FIGS. 1 to 3 are schematic views respectively illustrating three conventional LED packages packaged by different method. FIG. 1 illustrates a LED package 100 packaged by a traditional uniform distribution method.

As shown in FIG. 1, the phosphor 101 (including red, green or yellow phosphor) packaged by a traditional uniform distribution method seems can be uniformly distributed in a molding compound 102 molded on a substrate 104. However, as the distribution of the phosphor 101 can not be controlled very uniformly, it is difficult for the traditional method to make an LED package 100 having high color uniformity and high outputting lumen. To solve these problems, an electrophoresis coating technique is utilized to distribute the phosphor 101 around the LED die 103 in order to form a conformal distribution structure having uniform thickness on the surface of the LED die 103.

FIG. 2 illustrates a LED package 200 packaged by the aforementioned conformal distribution method. The advantage of using the conformal distribution method to coat the phosphor 101 is that the conformal distribution structure can convert the blue excitation light of the phosphor 101 into white light with great uniformity; thus this excellent color controlling ability may benefit the performance of the LED package 200.

However, the manufacturing cost of the electrophoresis coating technique is too high to satisfy the demand of reducing the selling price of the LED package 200. Moreover, because the phosphor 101 of the conformal structure may directly congregate on the surface of the LED die 103, the light absorption of the phosphor 101 per unit area is low. In addition, since the phosphor 101 is separated far away from the light emitting surface of the LED package 200, the excitation light of yellow or green phosphor may be easily absorbed by the red phosphor before emitting out of the light emitting surface, such that the light extraction efficiency of LED package 200 may be reduced.

To improve the light extraction efficiency of a LED package, a remote phosphor configuration technique is currently employed to coat the phosphor 101. FIG. 3 illustrates a LED package 300 packaged by the remote phosphor configuration technique in accordance with the prior art. The remote phosphor configuration technique includes coating a phosphor layer 301 on the molded molding compound 102 of the LED package 300; thus the phosphor layer 301 is separated away from the LED die 103 for a spatial separation rather than being direct in contact with the LED die 103. Because, this spatial separation can reduce the re-absorption phenomenon of the emitted light of the LED die 103 and avoid the degradation of the phosphor 301 resulted from the high temperature of the LED die 103, such that the light extraction efficiency and reliability of the LED package 300 can be significantly improved.

Besides, to improve the luminous flux of the LED package 300, a lens 310 is usually assembled on to the packaged LED package. However, the process for fabricating this structure which includes packaging a LED die 103 by a molding compound 102; forming a phosphor layer 301 on the surface of the molding compound 102 and disposing the lens 310 on the phosphor layer 301 may require two or more molding processes in the manufacturing process and make the manufacturing procedures more complex. Thus, it is difficult to reduce the manufacturing cost of the LED package 300.

In view of the foregoing situations, it is desirous to provide an improved LED package and a method for manufacturing the same in order to simplify the manufacturing process and greatly reduce the manufacturing cost without deteriorating the light extraction efficiency and the reliability of the LED package.

### SUMMARY OF THE INVENTION

One aspect of the invention is to provide a LED package, wherein the LED package comprises a substrate, at least one LED die, a lens and an in-mold decoration film. The LED die is fixed on the substrate. The lens is convexly molded on the substrate to encapsulate the LED die. The in-mold decoration film has at least one phosphor layer disposed on the lens and a surface treatment layer disposed on the phosphor layer.

In another embodiment of the invention, the lens consists of a transparent molding compound. In some embodiments of the invention, the transparent molding compound is formed by curing epoxy resin or silica gel. In another embodiment, the lens has a convex cambered surface.

In another embodiment of the invention, the surface treatment layer is a silica gel layer, an epoxy resin layer or other transparent material that can resist moisture and oxygen.

The invention also provides a method for manufacturing a LED package. In one embodiment, the method includes steps of providing a substrate having at least one LED die fixed thereon, and an in-mold decoration film having at least one phosphor layer and disposing a surface treatment layer on the phosphor layer are provided. Then, the in-mold decoration film is deformed to define at least one recess using the surface treatment layer served as an outer wall of the recess. Subsequently, the recess is filled with a transparent molding compound; and the substrate is assembled with the in-mold decoration film to make the LED die disposed in the recess and encapsulated in the transparent molding compound. The transparent molding compound is next cured to form a lens.

In another embodiment of the invention, the in-mold decoration film further comprises a carrier layer, a releasing film disposed on the carrier layer, wherein the surface treatment layer disposed on the releasing film and the phosphor layer disposed on the surface treatment layer. In another embodiment of the invention, the in-mold decoration film further comprises an adhesive layer disposed on the phosphor layer.

In another embodiment of the invention, the method further comprises a step of stripping the releasing film to separate the carrier layer from the surface treatment layer after the formation of the lens.

In another embodiment of the invention, the transparent molding compound is epoxy resin or silica gel.

In accordance with aforementioned embodiments of the invention, a LED package and a method for manufacturing the same are provided, wherein an in-mold decoration film having a phosphor layer and a surface treatment layer is utilized as an outer film to package a LED die. It means that only one molding process is required; nevertheless, an improved optical performance similar to that provided by a conventional LED package having a remote phosphor configuration structure can still be accomplished. Besides, a lens structure which can improve the light flux of the LED package is also provided by the same approach. In other words, while maintaining the light extraction efficiency and the reliability as the conventional LED package did, the embodiments of the invention can not only simplify the traditional LED packaging process but can also reduce the manufacturing cost significantly.

### BRIEF DESCRIPTION OF THE DRAWINGS

The above objects and advantages of the invention will become more readily apparent to those ordinarily skilled in the art after reviewing the following detailed description and accompanying drawings, in which:

FIG. 1 illustrates a LED package packaged by a traditional uniform distribution method;

FIG. 2 illustrates schematic view of a LED package packaged by a conformal distribution phosphor method in accordance with the prior art.

FIG. 3 illustrates a LED package packaged by a remote phosphor configuration technique in accordance with the prior art.

FIGS. 4A to 4F illustrate cross sectional views of the processing structures for manufacturing a LED package in accordance with one embodiment of the invention; and

FIG. 4G illustrates an enlarged cross sectional view of the LED package structure shown in FIG. 4F.

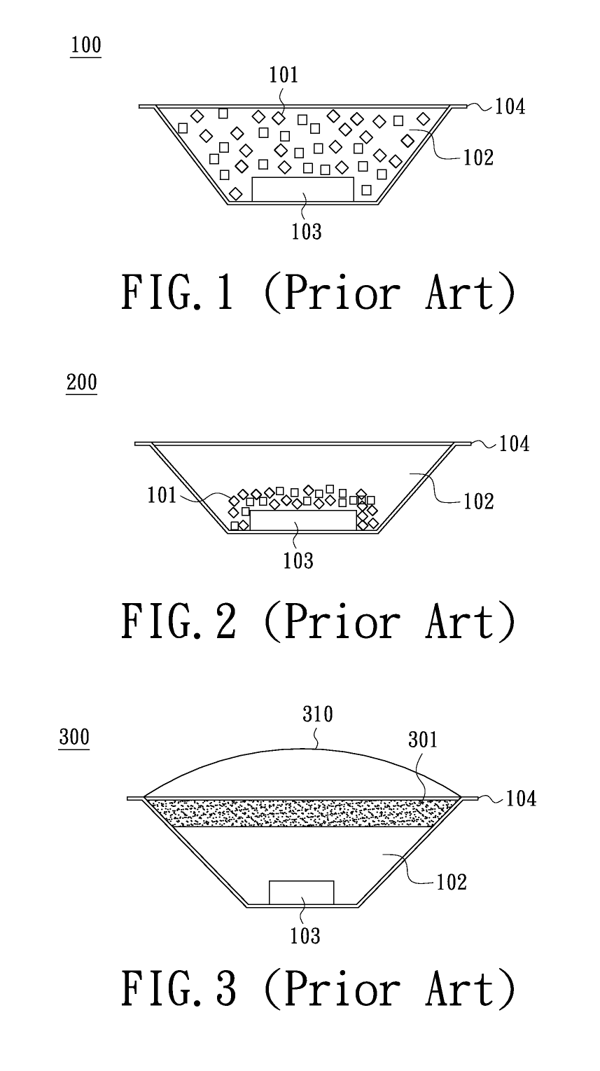

### DETAILED DESCRIPTION OF PREFERRED EMBODIMENTS

The invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

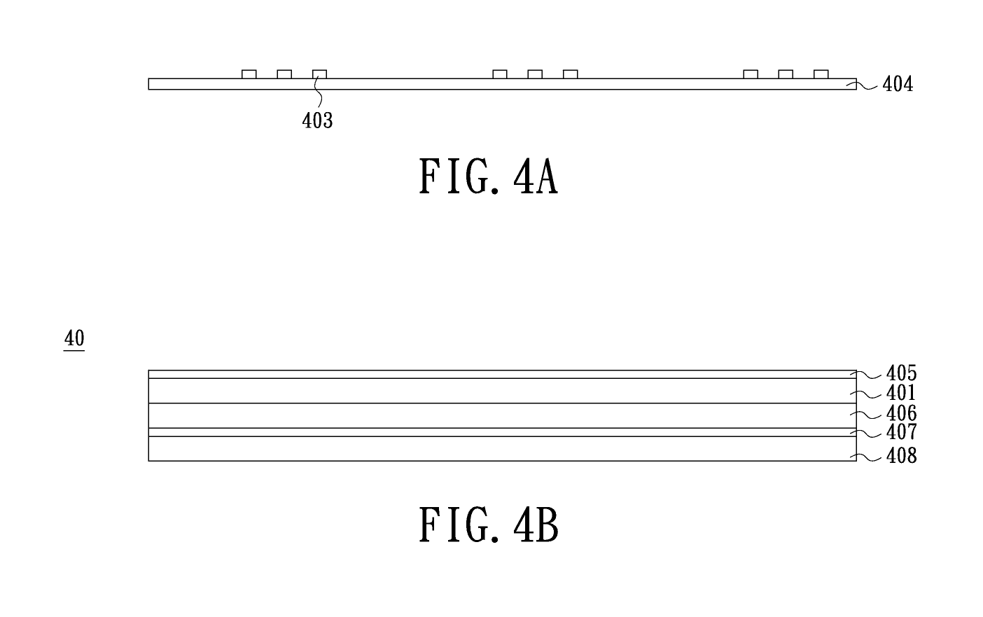

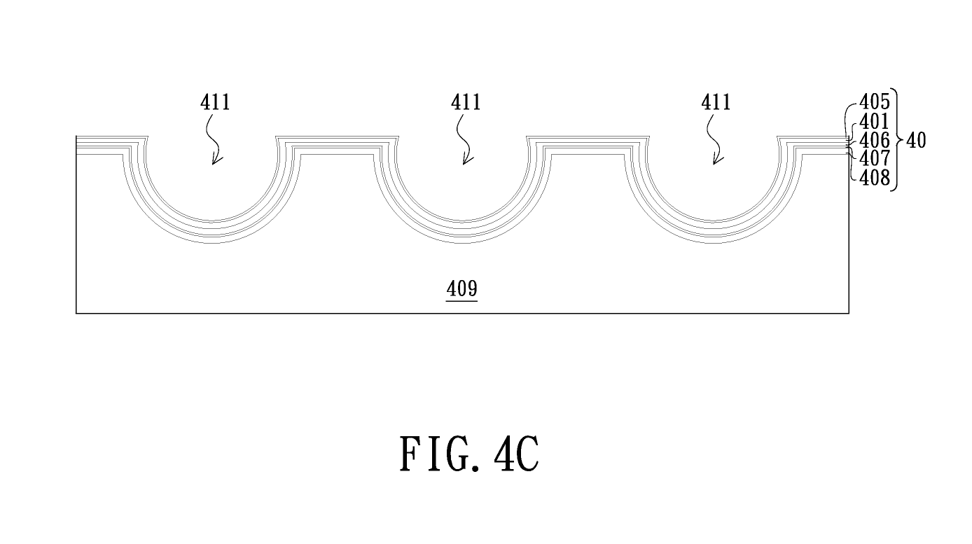

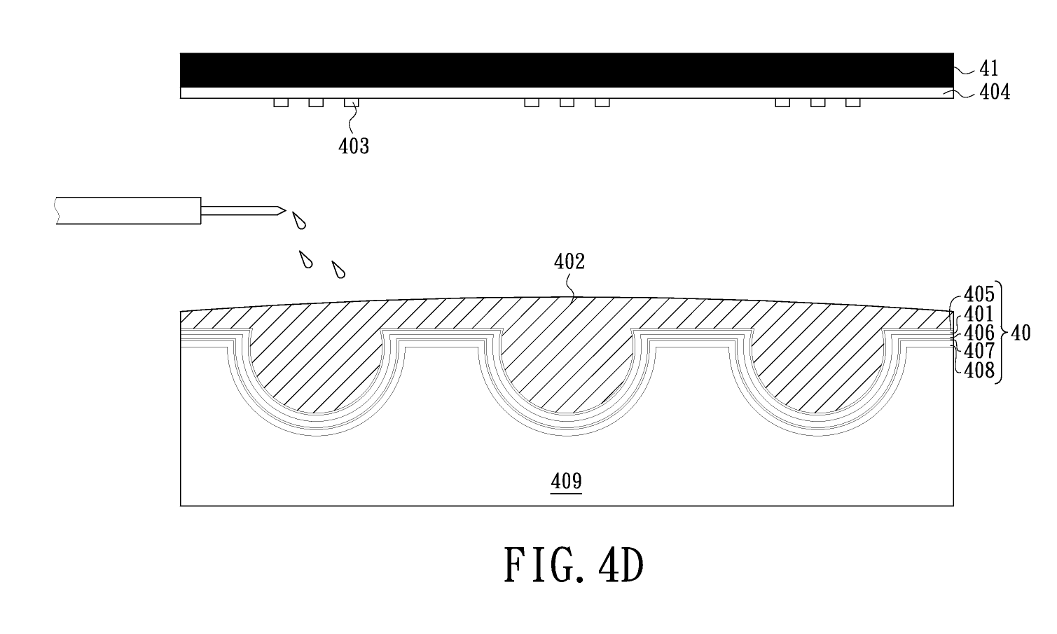

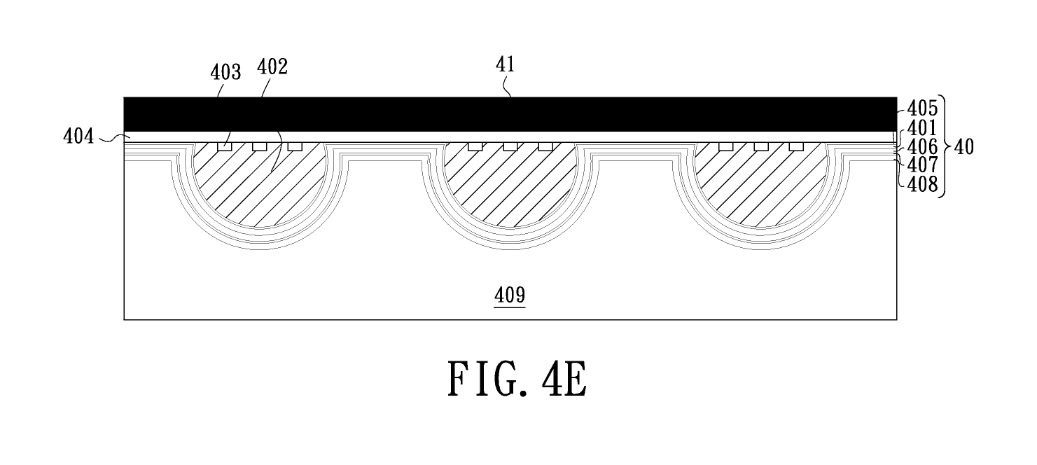

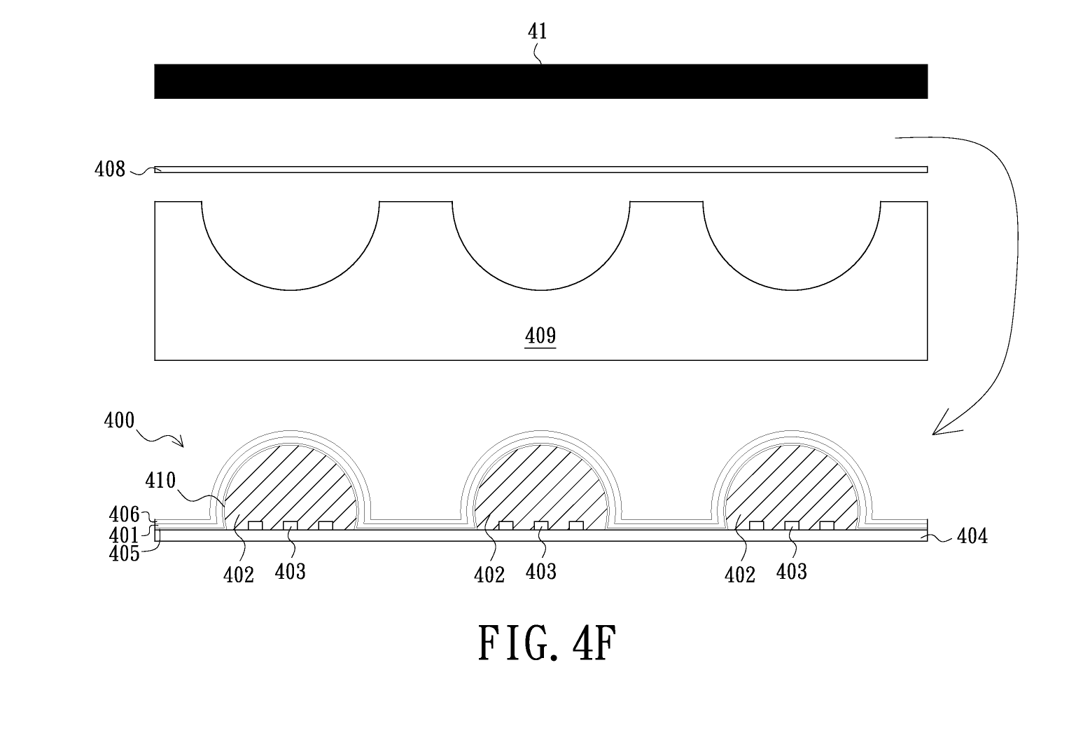

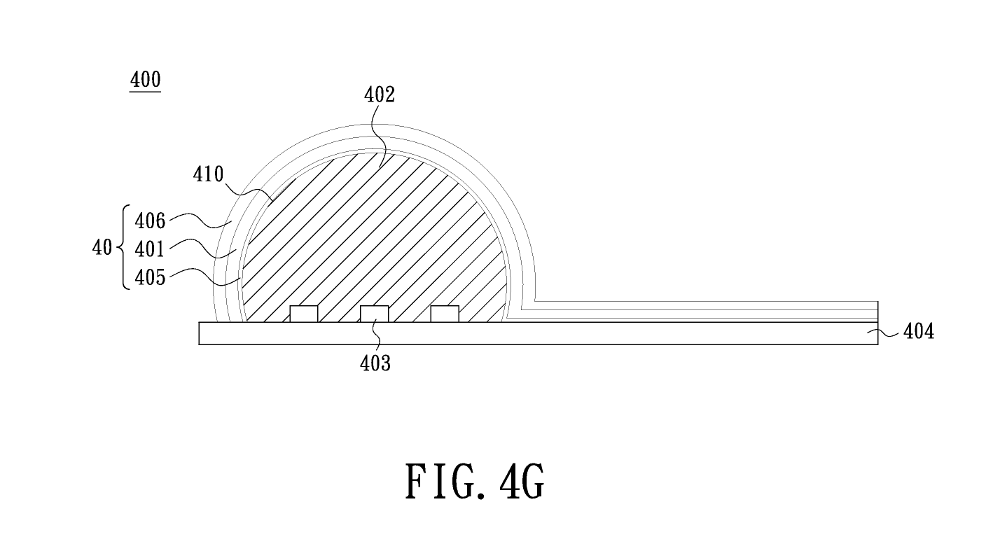

The invention provides a LED package and a method for manufacturing the same. FIGS. 4A to 4F illustrate cross sectional views of the processing structures for manufacturing a LED package 400 in accordance with one embodiment of the invention. The method comprises steps as follows. As shown in FIG. 4A, a substrate 404 is firstly provided wherein more than one LED dies 403 are fixed onto the substrate 404.

Also, a flexible in-mold decoration film 40 comprising a phosphor layer 401 and a surface treatment layer 406 is provided. In the embodiment, the in-mold decoration film 40 further comprises a carrier layer 408, a releasing film 407 and an adhesive layer 405, wherein the releasing film 407 is disposed on the carrier layer 408; the surfaced treated layer 406 is disposed on the releasing film; the phosphor layer 401 is disposed on the surface treatment layer 406; and an adhesive layer 405 is disposed on the phosphor layer 401(shown in FIG. 4B). It should be appreciated that the adhesive layer 405 of the in-mold decoration film 40 is optional, so that in some embodiments of the invention, the in-mold decoration film 40 may not comprise any adhesive layer.

The carrier layer 408 can be a flexible plastic substrate, e.g. a substrate consisting of polyethylene terephthalate (PET) or other polymeric materials with the likely characteristics. The releasing film 407 preferably consisting of polysiloxane. While the releasing film 407 is subjected to stress, heat or light, the carrier layer 408 can be separated from the in-mold decoration film 40. The surface treatment layer 406 possesses the characteristics of scratchproof, waterproof and moisture proof. In some embodiments, the surface treatment layer 406 can be a silica gel layer or an epoxy resin layer. The phosphor layer 401 preferably is formed by steps of mixing phosphor and adhesive and then coating the mixture onto the carrier layer 408. In some embodiments, the phosphor layer 401 is a thin visible-light excitation layer printed or coated on the carrier layer 408.

Subsequently, the in-mold decoration film 40 is deformed to define a plurality of recesses 411 using the surface treatment layer 406 serves as an outer wall of the recesses 411. In some embodiments, the deformation of the in-mold decoration film 40 comprises stamping the in-mold decoration film 40 with a stamping die 409. In the embodiment, the in-mold decoration film 40 is deformed by a vacuum lamination process to make the in-mold decoration film 40 conforming to the stamping die 409 (as shown in FIG. 4C). In an embodiment of, the stamping die 409 has a plurality of recesses and each of which has a cambered surface; thus each of the recesses 411 defined on the deformed in-mold decoration film 40 and conforming to the stamping die 409 has a concave cambered surface.

Next, the recesses 411 are filled with a transparent molding compound 402 (as shown in FIG. 4D). In some embodiments of the invention, the transparent molding compound 402 consists of melted epoxy resin. However, the high operating temperature of LED die 409 may trigger the epoxy resin undergoing deterioration, such as yellowing, and so as to lead the emitted light of the LED package 400 attenuated. Therefore, in the some preferred embodiments, melted epoxy resin can be substituted with silica gel which possesses characteristics of high reflectivity, heat-resistance, good insulation, chemical stability, high light transmittance (for the light in the wavelength range from 300 to 700 nm), and high reliability serves as the transparent molding compound 402.

Thereafter, the substrate 404 and the in-mold decoration film 40 are assembled to make each of the LED dies 403 disposed in one of the recesses 411 and encapsulated in the transparent molding compound 402 (as shown in FIG. 4E). In the embodiment, to assemble the substrate 404 and the in-mold decoration film 40, the substrate 404 having the LED dies 403 fixed thereon is sucked by a tool 41 (as shown in FIG. 4D), and then is pressed onto the deformed in-mold decoration film 40 which is carried by the stamping die 409 and contains the transparent molding compound 402. In some embodiments, each of the LED dies 403 is corresponding to one of the recesses, thus each recess may be allocated one or more LED dies 403 according to the design of the LED package 400.

After the transparent molding compound 402 is cured to form a lens 410, the assembled substrate 404 and the in-mold decoration film 40 are then released from the stamping die 409, and the carrier layer 408 is separated from the in-mold decoration film 40 by stress, heat or light to form a plurality of LED package 400 as shown in FIG. 4F.

FIG. 4G illustrates an enlarged cross sectional view of the LED package 400 structure shown in FIG. 4F. Referring to FIG. 4F, the LED package 400 comprises a substrate 404 having at least one LED die 403 fixed thereon; a lens 410 consisting of cured transparent molding compound 402 molded on the substrate 404 in order to encapsulate the LED die 403; and an in-mold decoration film 40 comprising a phosphor layer 401 disposed on the lens 410; and a surface treatment layer 406 disposed on the phosphor layer 401.

In the preferable embodiment, the surface treatment layer 406 is a silica gel layer; the phosphor layer 401 is a thin phosphor coating layer. Additionally, in another embodiment, an optional adhesive layer 405 can be disposed between the phosphor layer 401 and the lens 410. The transparent molding compound 402 which is cured to form the lens 410 can be silica gel.

In accordance with aforementioned embodiments, a LED package and a method for manufacturing the same are provided. In the embodiments, an in-mold decoration film having a phosphor layer and a surface treatment layer is utilized as an outer film to package a LED die, wherein the surface treatment layer is deformed to identify at least one recess using the surface treatment layer serves as an outer wall of the recess; and the recess is then filled with a transparent molding compound which can be cured to form a lens after the substrate is assembled with the in-mold decoration film to dispose the LED die in the recess, thereby the LED die fixed on the substrate can be capsulated in the lens by merely single one molding process.

In other words, an improved optical performance similar to that provided by a conventional LED package having a remote phosphor configuration structure can be accomplished by the embodiments of the invention; nevertheless, merely one molding process is required. Besides, a lens structure which can improve the light flux of the LED package is also provided by the same approach. Therefore, while maintaining the light extraction efficiency and the reliability as the conventional LED package did, the embodiments not only can simplify the traditional LED packaging process but also can reduce the manufacturing cost significantly.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A light emitting diode package, comprising:
a substrate;
at least one light emitting diode (LED) die fixed on the substrate;
a lens convexly molded on the substrate to encapsulate the LED die; and
an in-mold decoration film having at least one phosphor layer disposed on the a lens and a surface treatment layer disposed on the phosphor layer.

2. The LED package of claim 1, wherein the lens consists of a transparent molding compound.

3. The LED package of claim 1, wherein the transparent molding compound is formed by curing epoxy resin or silica gel.

4. The LED package of claim 1, wherein the lens comprises a convex cambered surface.

5. The LED package of claim 1, wherein the surface treatment layer is a silica gel layer or an epoxy resin layer.

6. A method for manufacturing a LED package, comprising:
providing a substrate having at least LED die fixed thereon;
proving an in-mold decoration film having a phosphor layer and a surface treatment layer disposed on the phosphor layer;
deforming the in-mold decoration film to defining at least one recess using the surface treatment layer serves as an outer wall of the;
filing the recess with a transparent molding compound;
assembling the substrate and the in-mold decoration to make the LED die disposed in the recess and encapsulated in the transparent molding compound; and
curing the transparent molding compound to from a lens.

7. The method for manufacturing the LED package of claim 6, wherein the in-mold decoration film further comprises a carrier layer, a releasing film formed on the carrier layer, wherein the surface treatment layer disposed on the releasing film and the phosphor layer disposed on the surface treatment layer.

8. The method for manufacturing the LED package of claim 7, wherein the in-mold decoration film further comprises an adhering layer disposed on the phosphor layer.

9. The method for manufacturing the LED package of claim 7, further comprising stripping the releasing film to separate the carrier layer from the surface treatment layer after the formation of the lens.

10. The method for manufacturing the LED package of claim 6, wherein the transparent molding compound is epoxy resin or silica gel.
